(19) United States
(12) Patent Application Publication
(10) Pub. No.: US 2026/0231450 A1
(43) Pub. Date: Aug. 6, 2026

(54) METHOD OF MANUFACTURING AN ELECTRONIC DEVICE

(71) Applicant: STMicroelectronics International N.V., Geneva (CH)

(72) Inventors: Alexis GAUTHIER, Meylan (FR); Pascal CHEVALIER, Chapareillan (FR)

(73) Assignee: STMicroelectronics International N.V., Geneva (CH)

(21) Appl. No.: 19/463,302

(22) Filed: Jan. 29, 2026

(30) Foreign Application Priority Data
Jan. 31, 2025 (FR) FR2500989

(51) Int. Cl. H10D 10/01; H10D 10/40

(52) U.S. Cl. CPC H10D 10/051; H10D 10/40

(57) ABSTRACT

An electronic device including a bipolar transistor is manufactured by: a) forming an intrinsic base region and then b) forming an emitter region, where there is no formation of a layer of dielectric material separating the intrinsic base region and the emitter region. Prior to a), the manufacture of bipolar transistor includes: c) forming a first part of a collector region of the transistor in a support; d) forming a stack of dielectric layers on the support, where the stack includes, over the support, a second layer of dielectric material, a third layer of dielectric material, and a fourth layer of dielectric material; and e) forming a cavity through the stack so as to reach the first part of the collector region, with the intrinsic base region being formed, in step a), in the cavity.

### PRIORITY CLAIM

This application claims the priority benefit of French Application for Patent No. FR2500989, filed on January 31, 2025, the content of which is hereby incorporated by reference in its entirety to the maximum extent allowable by law.

### TECHNICAL FIELD

The present disclosure relates generally to electronic devices and manufacturing methods and, more specifically, to devices comprising a bipolar transistor and manufacturing methods.

### BACKGROUND

A bipolar transistor is a semiconductor-based electronic device from the transistor family. Its operating principle is based on two PN junctions, one forward and one reverse.

Manufacturing methods for bipolar transistors include steps for forming an emitter region. Such steps can have drawbacks.

### SUMMARY

One embodiment provides a method of manufacturing of an electronic device comprising a bipolar transistor, the method comprising steps: a) forming an intrinsic base region; then b) forming an emitter region, the method not comprising the formation of a first layer of dielectric material separating the intrinsic base region and the emitter region.

According to one embodiment, the method comprises, prior to step a): step c) forming a first part of a collector region of the transistor in a support; step d) forming a stack of dielectric layers on the support, the stack comprising, from the support, second, third and fourth layers of dielectric materials; and step e) forming a cavity through the stack so as to reach the first part of the collector region, the intrinsic base region being formed, in step a), in the cavity.

According to one embodiment, the method does not involve forming a spacer in the cavity.

According to one embodiment, at least one horizontal dimension of the cavity is less than 150 nm.

According to one embodiment, the method comprises, between steps a) and b), step f) forming a layer of semiconductor material in the cavity, the method not comprising the formation of a first layer of dielectric material separating the layer of semiconductor material from the emitter region.

According to one embodiment, during step b), the emitter region is formed so as to fill the cavity.

According to one embodiment, step b) is followed by step g) forming a fifth layer of dielectric material so as to fill the cavity.

According to one embodiment, step d) comprises forming a sixth layer of dielectric material of the stack, and wherein the method comprises, after step b), step h) removing the sixth layer of dielectric material.

According to one embodiment, step b) comprises: step b1) forming a layer of emitter region material, the layer of emitter region material covering the fourth layer; step b2) forming a seventh layer of dielectric material covering the layer of emitter region material; and step b3) partially etching the layer of the material of the emitter region and the seventh layer of dielectric material.

According to one embodiment, the method further comprises steps: i) forming an eighth layer of dielectric material, in a conformal manner, on the device; j) etching the fourth and eighth layers of dielectric material so as to encapsulate the emitter region; k) removing the third layer of dielectric material; and l) forming an extrinsic base region of the transistor.

According to one embodiment, step j) comprises the formation of an etch mask covering the emitter region.

According to one embodiment, step j) comprises anisotropic etching.

According to one embodiment, the method comprises, between steps h) and i), etching a peripheral portion of the emitter region.

Another embodiment provides an electronic device comprising a bipolar transistor, the bipolar transistor comprising an intrinsic base region and an emitter region and not comprising a first layer of a dielectric material separating the intrinsic base region and the emitter region.

According to one embodiment, the emitter region has sidewalls coplanar with the sidewalls of the intrinsic base region.

According to one embodiment, the emitter region extends partially opposite to the intrinsic base region.

According to one embodiment, the emitter region extends opposite to the entirety of the intrinsic base region and partially opposite to the extrinsic base region.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates an example of an electronic device;

FIGS. 2A to 2H illustrate structures resulting from steps in a manufacturing method of the electronic device of FIG. 1;

FIG. 3 illustrates another example of an electronic device;

FIGS. 4A to 4F illustrate structures resulting from steps in another embodiment of a manufacturing method of the electronic device shown in FIG. 3;

FIG. 5 illustrates another example of an electronic device; and

FIGS. 6A to 6C illustrate structures resulting from steps in another embodiment of a manufacturing method of the electronic device shown in FIG. 5.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10 % or 10°, and preferably within 5 % or 5°.

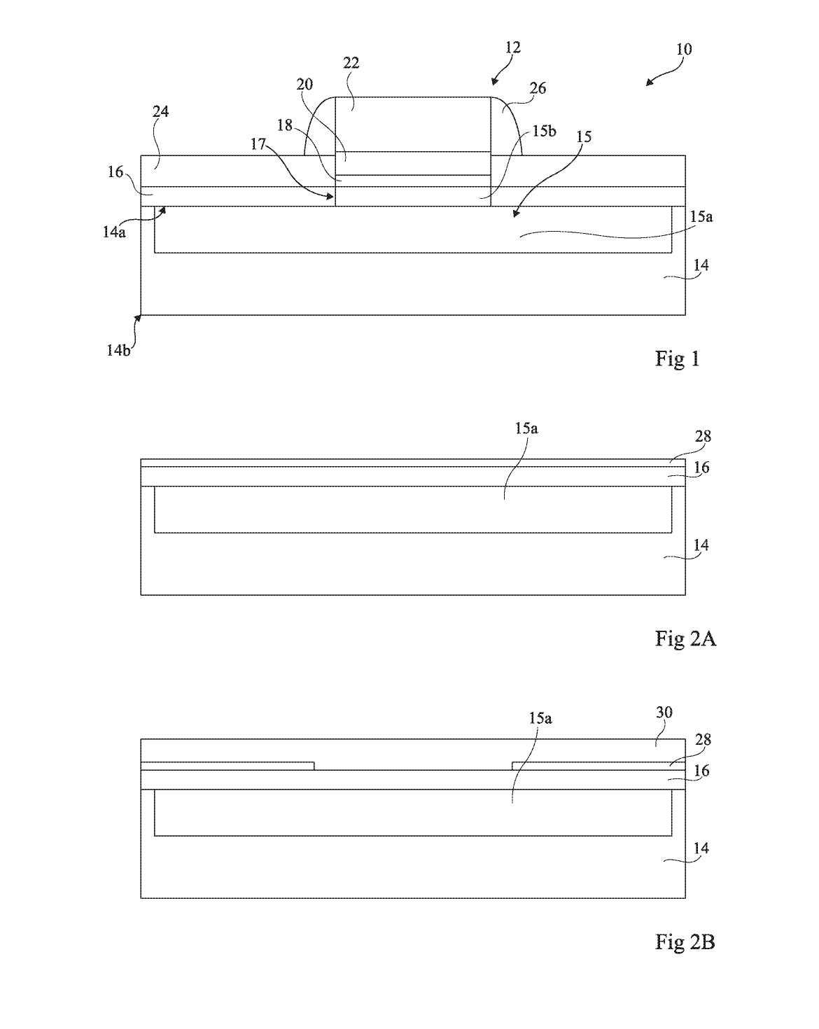

FIG. 1 illustrate an embodiment of an electronic device 10. The device 10 comprises a bipolar transistor 12.

The device 10 comprises a support 14, for example a semiconductor substrate, for example made of silicon, for example made of undoped silicon. The support comprises an upper face 14a and a lower face 14b, opposite the upper face. The transistor 12 is formed in and on the support 14.

Transistor 12 comprises a collector 15. The collector comprises a first part 15a and a second part 15b. Part 15a is located in the support 14. Part 15a is, for example, a semiconductor region in the substrate support 14. Part 15a is, for example, made of a same material as the support 14, for example made of silicon. Part 15a is doped with a first conductivity type, N-type or P-type, preferably N-type. The upper face of the first part 15a is flush with the upper face of the support 14. The upper faces of the support 14 and part 15a are therefore coplanar.

The device 10 comprises an insulating layer 16. The layer 16 is made of a dielectric material, such as silicon oxide. The layer 16 covers the upper face of the support 14 and, for example, the layer 16 partially covers the part 15a. The layer 16 comprises an opening 17 passing through layer 16 to the upper face of a portion of part 15a. The opening 17 extends from the front to the rear of the layer 16. The opening 17 thus uncovers the upper face of the part 15a. The opening 17 preferably has at least one horizontal dimension of less than 200 nm, for example of less than 150 nm, for example substantially equal to 100 nm.

The part 15b of the collector 15 is located in, preferably only in, the opening 17. The part 15b preferably fills the opening 17. The part 15b is located on, and in contact with, the part 15a. The lower face of the part 15b is thus preferably only in contact with the part 15a. The part 15b is made of a semiconductor material, preferably epitaxial. The part 15b is made of a doped material of the same conductivity type as the part 15a, for example N-type.

The transistor further comprises a stack of the layers 18, 20, 22. The layers 18, 20, 22 have side faces that are preferably in alignment with each other, and thus share coplanar side faces. The side faces of layers 18, 20, 22 are also preferably in alignment with, and thus shares a coplanar side face, with the side faces of the part 15b. Thus, the upper face of the part 15b is preferably entirely covered by the layer 18. The lower face of the layer 18 is preferably in contact only with the part 15b. The upper face of the layer 18 is preferably entirely covered by the layer 20. The lower face of the layer 20 is preferably in contact only with the layer 18. The upper face of the layer 20 is preferably entirely covered by the layer 22. The lower face of the layer 22 is preferably in contact only with the layer 20. Thus, the lower face of the layer 22 preferably has the same dimensions as the upper face of the layer 20. The layer 20 and the layer 22 are not separated, even partially, by an insulating layer.

The layer 18 is an intrinsic base layer. The layer 18 thus forms part of the base of transistor 12. The layer 18 is made of a semiconductor material, such as silicon, for example epitaxial silicon, doped with a second conductivity type, opposite to the first conductivity type. The layer 18 is, for example, P-type doped.

The layer 20 is made of a semiconductor material, such as silicon, for example epitaxial silicon. Preferably, the layer 20 is undoped.

The layer 22 is an emitter layer. The layer 22 thus corresponds to the emitter of the transistor 12. The layer 22 is made of a semiconductor material, for example silicon, for example epitaxial silicon, doped with the first conductivity type. The layer 20 is, for example, N-type doped.

The transistor further comprises an extrinsic base region 24. The region 24 extends around, and in contact with, the stack of layers 18, 20, 22. More specifically, the region 24 is in contact with the side walls (or faces) of certain layer(s) of the stack, and more particularly of the layer 18. In the example shown in FIG. 1, the region 24 is also in contact with the side walls of the layer 20. Preferably, the region 24 is not in contact with the layer 22. The region 24 extends over the layer 16.

The transistor also comprises spacers 26, for example made of a dielectric material, covering the side walls of the stack of layers 18, 20, 22. The spacers 26 thus cover, preferably entirely, the side walls of the layer 22, and cover, for example at least partially, the side walls of the layer 20. The spacers 26 rest, for example, on the upper face of the layer 24.

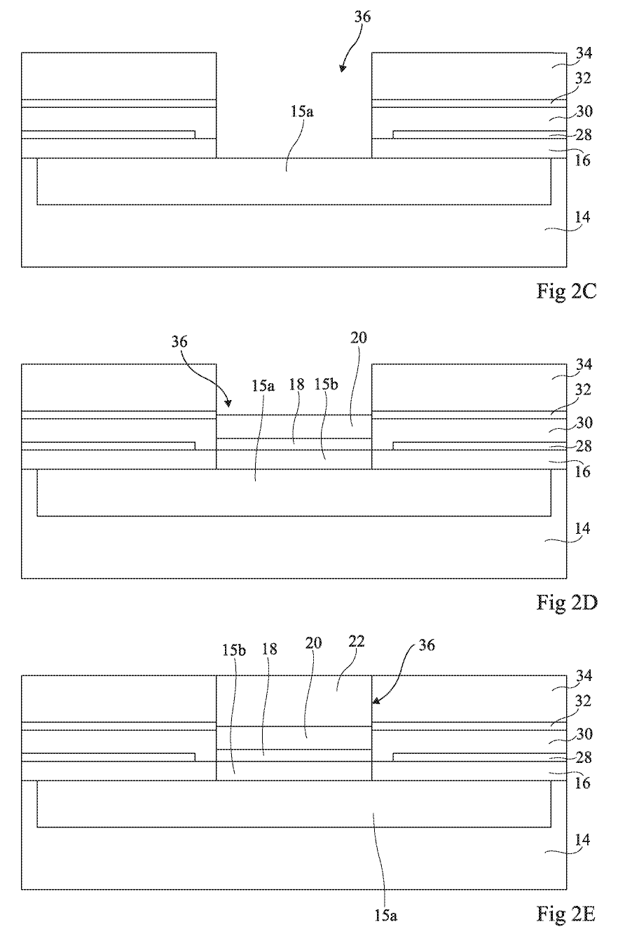

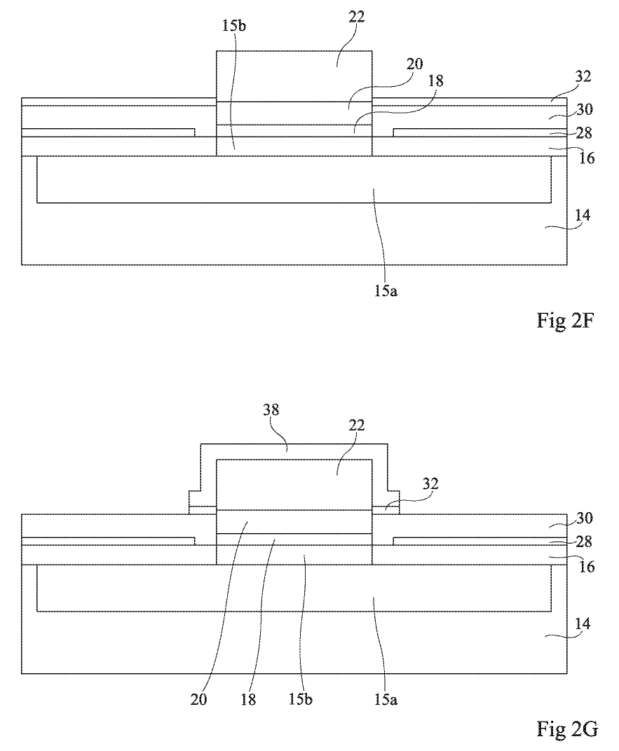

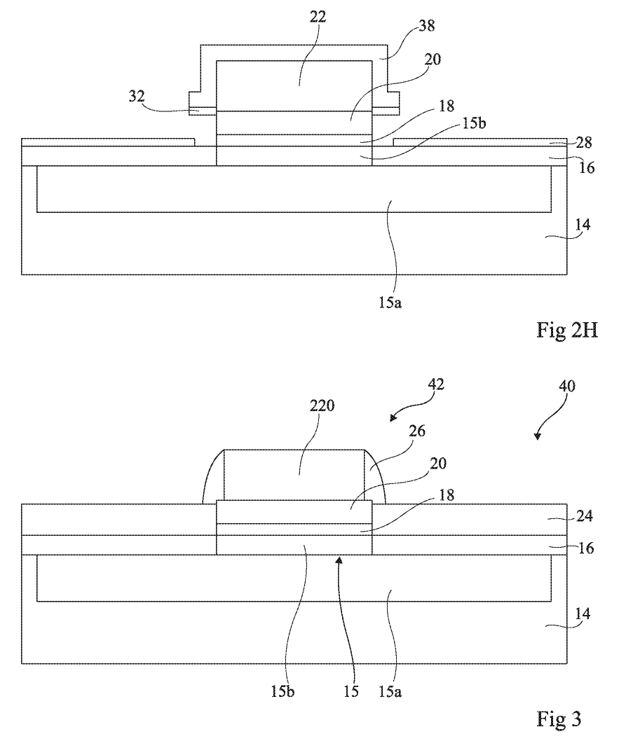

FIGS. 2A to 2H illustrate structures resulting from steps, preferably successive, of a manufacturing method of the electronic device of FIG. 1.

FIG. 2A illustrates a structure resulting from a step in a manufacturing method of the electronic device shown in FIG. 1.

During this step, the collector region 15a is formed in the support 14.

During this step, the insulating layer 16 is formed on the substrate 14. During this step, the layer 16 preferably completely covers the entirety of the upper face 14a of the layer 14 at the transistor location.

In addition, the step shown in FIG. 2A comprises, for example, the formation of a layer 28. The layer 28 covers the layer 16. During this step, the layer 28 preferably completely covers the upper face of the layer 16. The layer 28 is thus entirely separated from the substrate 14 by the layer 18. The layer 28 is made of a material suitable for epitaxial growth of a semiconductor material. Preferably, the layer 28 is made of a material enabling a semiconductor material to grow non-selectively on said layer 28, for example during a selective epitaxial growth step. For example, the layer 28 is made of amorphous silicon, or polycrystalline silicon.

According to another embodiment, the method does not include the formation of the layer 28.

FIG. 2B illustrates a structure resulting from a step in a manufacturing method of the device shown in FIG. 1.

During this step, layer 28 is etched. For example, portions of the layer 28 located at the layer 20 locations are removed. An opening is thus formed in the layer 28 in order to expose a portion of the layer 16 facing region 15a.

The step shown in FIG. 2B further comprises the formation, preferably over the entire structure, on the upper face of the structure, of a layer 30 made of a dielectric material, for example made of silicon nitride. The layer 30 covers the layer 28 and the portion of the layer 16 exposed by the opening in the layer 28. This layer is a conformal layer and will, in practice, include a drop in the upper surface at or about the location of the opening in layer 28 (that drop in upper surface not being explicitly shown in the FIG. 2B).

FIG. 2C illustrates a structure resulting from a step in a manufacturing method of the device shown in FIG. 1.

The step shown in FIG. 2C comprises the formation of a layer 32 over the entire structure resulting from the step shown in FIG. 2B. The layer 32 is made of a dielectric material, preferably of a material different from the material of the layer 30, preferably of a material that can be selectively etched with respect to the material of the layer 30, for example made of silicon oxide. The layer 32 preferably completely covers the layer 30. The layer 32 is preferably in contact with the upper face of the layer 30.

The step shown in FIG. 2C comprises the formation, preferably over the entire layer 32, of a layer 34. The layer 34 is made of a dielectric material, preferably of a material different from the material of the layer 32, preferably of a material that can be selectively etched with respect to the material of the layer 32. The layer 34 is preferably in contact with the upper face of the layer 32. The layer 34 is made of the same material as layer 30, for example made of silicon nitride.

The stack of layers 16, 28, 30, 32, 34 preferably has a total thickness substantially equal to the total thickness of the layers 15b, 18, 20, 22. The thickness of the layer 34 is preferably greater than or equal to the thickness of the layer 22.

The step shown in FIG. 2C further comprises a step of etching a cavity 36. The cavity 36 passes through layers 16, 28, 30, 32, 34. The cavity 36 preferably does not extend into the substrate 14. Similarly, the cavity 36 preferably does not extend into the collector region 15a. The cavity 36 thus passes through the layer 30 at a location where the layer 28 has been etched. In particular, the cavity 36 is located at the location of the layers 16, 18, 20, 22.

The cavity 36 preferably has at least one horizontal dimension, that is, a dimension in a plane parallel to the upper face of the part 15a, of less than 200 nm, for example of less than 150 nm, for example substantially equal to 100 nm.

The cavity 36 preferably has straight walls. In other words, the side walls of layers 16, 30, 32, 34 forming the walls of the cavity 36 are coplanar. Preferably, the walls of the cavity 36 are substantially perpendicular to the upper face of the support 14, that is, forming an angle substantially equal to 90°.

FIG. 2D illustrates a structure resulting from a step in a manufacturing method of the device shown in FIG. 1.

During this step, the part 15b is formed in the cavity 36. In particular, the step shown in FIG. 2D comprises an epitaxial growth step so as to form the part 15b from the part 15a. The growth step is preferably maintained in such a way that the part 15b completely covers the portion of the part 15a exposed by the cavity 36. The growth step is preferably maintained in such a way that part 15b has a height substantially equal to the height of the layer 16.

During this step, the layer 18 is formed in cavity 36. Specifically, the step shown in FIG. 2D comprises an epitaxial growth step to form the layer 18 from the part 15b. The growth step is preferably maintained so that the layer 18 completely covers the part 15b.

During this step, the layer 20 is formed in cavity 36. Specifically, the step shown in FIG. 2D comprises an epitaxial growth step to form the layer 20 from the layer 18. The growth step is preferably maintained such that the layer 20 completely covers the layer 18.

FIG. 2E illustrates a structure resulting from a step in a manufacturing method of the device shown in FIG. 1.

During this step, the layer 22 is formed in the cavity 36. In particular, the step shown in FIG. 2E comprises an epitaxial growth step for forming the layer 22 from the layer 20. The growth step is preferably maintained so that the layer 22 completely covers the layer 20. The layer 22 is preferably formed so as to fill the cavity 36.

The layer 20 and the layer 22 are not separated, even partially, by an insulating layer. The method does not include, between the formation of the layer 20 and the formation of the layer 22, the formation of a dielectric layer in the cavity 36. The method does not include, between the formation of the layer 20 and the formation of the layer 22, the formation of spacers in the cavity 36.

Note: the layers 15b, 18, 20 and 22 are formed by epitaxy in the cavity 36. Therefore, the dimensions of the layers 15b, 18, 20 and 22 are defined by the dimensions of the cavity 36. The manufacture of the layers 15b, 18, 20 and 22 to provide the structure shown in FIG. 1 does not utilize a step of etching the layers 15b, 18, 20 and 22 to obtain desired dimensions. Rather, the formation of the layers 15b, 18, 20 and 22 is auto-aligned by the formed cavity 36, nd thus there is advantageously not a risk of misaligning etching mask, as may for example be used in prior art manufacturing methods, when forming the dimensions of layers 15b, 18, 20 and 22.

Thus, the dimensions of the interface between the emitter 22 and the base 18, through the layer 20, of the transistor are defined by the dimensions of the cavity 36. The dimensions of the interface between the emitter and the base of the transistor and the height of the emitter are not dependent on the features of any spacers that would be formed in the cavity 36. The emitter 22 can thus have dimensions smaller than those of a transistor comprising spacers between the layers 20 and 22. For example, the emitter, that is, the region 22, has a thickness of less than 100 nm.

The layers 15b, 18, 20 and 22 are formed by epitaxy in the cavity 36. Therefore, the dimensions of the layers 15b, 18, 20, 22 are defined by the cavity 36. The method of manufacturing the structure of FIG. 1 does not comprises a step of etching the layers 15b, 18, 20, 22 in order to obtain the wanted dimensions. The formation is auto-aligned and there is not risk of misaligning an etching mask in the formation of the layers 15b, 18, 20, 22.

FIG. 2F illustrates a structure resulting from a step in a manufacturing method of the device shown in FIG. 1.

During this step, the layer 34 is removed, preferably completely removed. The layer 34 is, for example, etched. The side walls of the layer 22, that is the emitter of the transistor 12, are at least partially exposed. The upper face of the layer 32 is, for example, fully exposed.

FIG. 2G illustrates a structure resulting from a step in a manufacturing method of the device shown in FIG. 1.

During this step, a layer 38 of dielectric material is formed, preferably in a conformal manner, on the structure resulting from the step in FIG. 2F. Thus, the layer 38 covers, and is preferably in contact with, the upper face of the layer 22, the side walls of the layer 22 and the upper face of the layer 32. The layer 38 is, for example, made of the same material as the layer 32, for example made of silicon oxide.

The step in FIG. 2G further comprises a step of etching the layers 32 and 38 so as to retain the portions of the layers 32 and 38 encapsulating the layer 22. More specifically, the step comprises the formation of an etch mask covering the layer 38 at and around the layer 22. The portions of the layer 32 and of the layer 38 that are not covered by the mask are then etched. In this way, all sides of the layer 22 are covered by the layer 32, the layer 38 or the layer 20. The upper face of the layer 30 is thus exposed, preferably entirely, except for the portions located directly around the layer 22.

FIG. 2H illustrates a structure resulting from a step in a manufacturing method of the device shown in FIG. 1.

During this step, the layer 30 is removed, for example by chemical etching. The side walls of the layer 18 are exposed. Similarly, the layer 28, and in particular the upper face of the layer 28, is exposed.

The method of manufacturing the device shown in FIG. 1 further comprises steps following the step described in connection with FIG. 2H. Thus, the method includes a step of forming the extrinsic base, for example by epitaxial growth of the layer 28 so as to form the layer 24. Epitaxial growth is thus maintained in such a way that the layer 24, formed from the layer 28, is in contact with the layer 18 and, for example, reaches the underside of the layer 32.

The manufacturing method also comprises, for example, a step for removing the layers 32 and 38 forming the encapsulation and forming the spacers 26 on the walls of the layer 22.

FIG. 3 illustrates a further embodiment of an electronic device 40. The device 40 comprises a bipolar transistor 42.

The device 40 comprises the elements of the device 10 shown in FIG. 1. With the exception of the layer 22, the elements of device 10 are present in the device 40 as described in relation to FIG. 1. Thus, the device 40 comprises the support 14, the collector 15, the dielectric layer 16, the intrinsic base 18, the extrinsic base 28, the semiconductor layer 20 and the spacers 26.

The device 40 comprises a layer 220 replacing the layer 22 of the device 10. The layer 220 of the device 40 differs from the layer 22 of the device 10 in that the horizontal dimensions of the layer 220 of the device 40 are smaller than the horizontal dimensions of the layer 22 of the device 10. More specifically, the horizontal dimensions of the layer 220 are smaller than the horizontal dimensions of the layers 18 and 20. Part of the upper face of the layer 20 is thus not covered by the layer 220 and is covered by the spacers 26. Like the layers 20 and 22 in FIG. 1, the layer 20 and layer 220 are not separated, even partially, by an insulating layer.

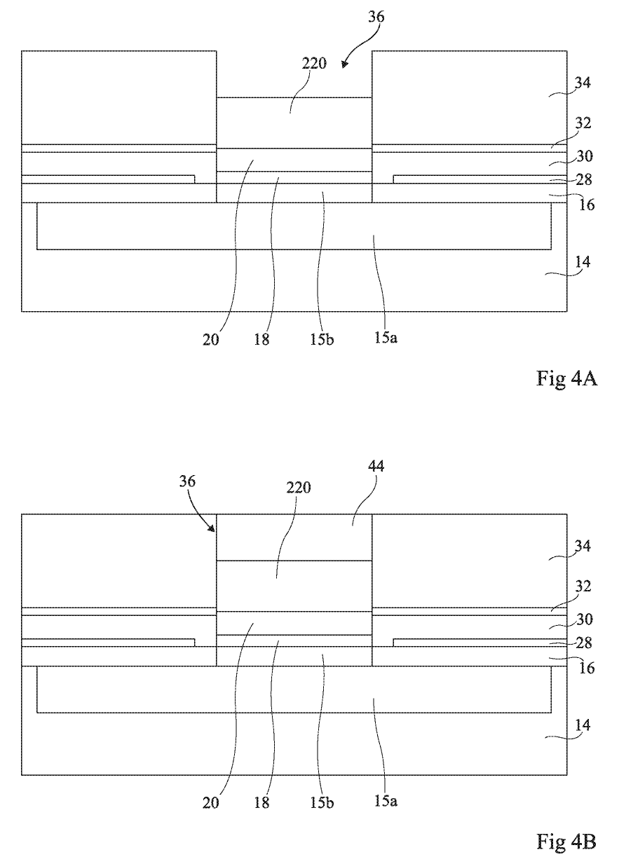

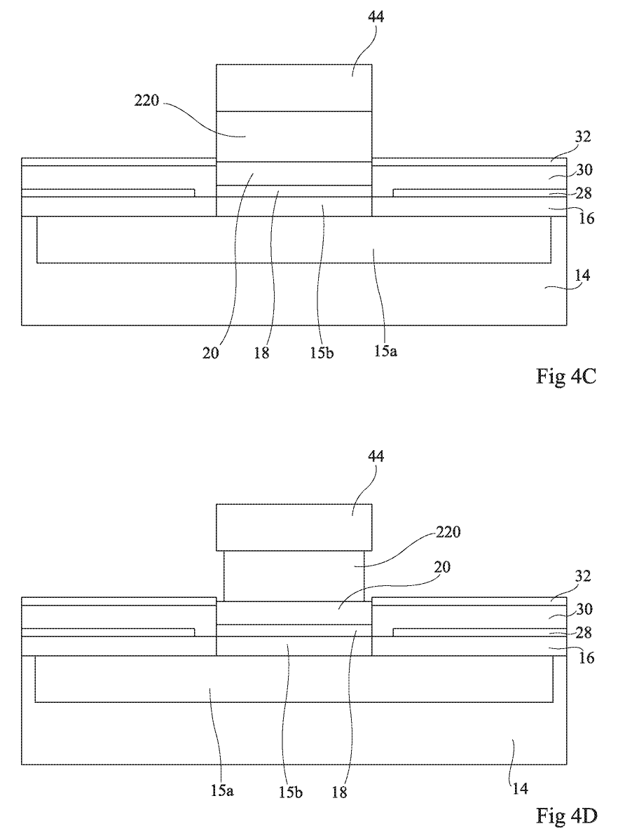

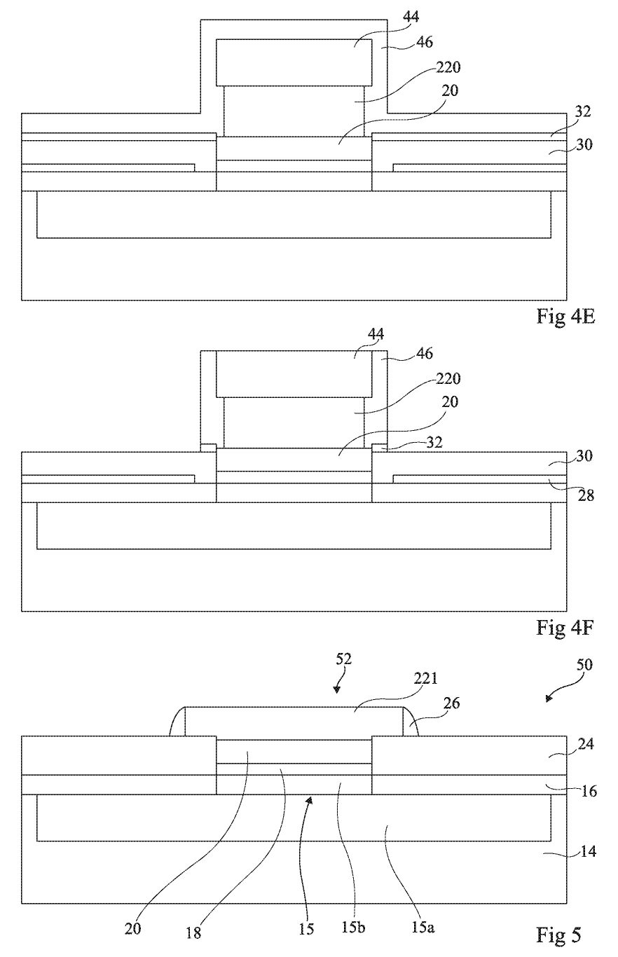

FIGS. 4A, 4B, 4C, 4D, 4E and 4F illustrate structures resulting from steps, preferably successive steps, in another embodiment of a manufacturing method of the electronic device 40 of FIG. 3.

FIG. 4A illustrates a structure resulting from a step in a manufacturing method of the device shown in FIG. 3. More specifically, FIG. 4A illustrates a structure resulting from steps identical to those described in relation to FIGS. 2A to 2E with the exception of the height of the layer 34, in which the layer 220 replaces the layer 22.

As in the method shown in FIGS. 2A to 2H, the layer 20 and layer 220 are not separated, even partially, by an insulating layer. The method does not comprise, between the formation of the layer 20 and the formation of the layer 220, the formation of a dielectric layer in the cavity 36. The method does not include, between the formation of the layer 20 and the formation of the layer 220, the formation of spacers in the cavity 36.

In the manufacturing method of the device shown in FIG. 3, the height of the layer 34 is greater than the height of the layer 220. This means that the layer 220 formed in the cavity 36 does not fill the cavity 36. The upper face of the layer 220 is thus located at a level closer to the layer 20 than the upper face of the layer 34.

Preferably, the distance between the level of the upper face of the layer 220 and the level of the upper face of the layer 34 is greater than the thickness of the layer 32, for example greater than 12 nm.

FIG. 4B illustrates a structure resulting from a step in a manufacturing method of the device shown in FIG. 3.

During this step, a region, or the layer, 44 of dielectric material is formed on the upper face of the layer 220, in the cavity 36. Preferably, the region 44 is made of the same material as the layer 32, for example made of silicon oxide. Preferably, the region 44 fills the cavity 36. Thus, preferably, the upper face of the layer 44 is coplanar with the upper face of the layer 34. For example, the region 44 is thicker than the layer 32.

According to one embodiment, the region 44 is formed by conformal deposition of a layer of the material of the region 44, for example made of oxide, over the entire structure. Said layer has a thickness at least equal to that of the region 44. Preferably, said layer fills the cavity 36. The formation of the region 44 then comprises a mechanical-chemical polishing step stopping on the upper face of the layer 34. Since the materials of the layer 34 and the region 44 can be etched selectively with respect to each other, the layer 34 serves as an etch stop layer.

According to another embodiment, the region 44 is formed on the upper face of the layer 220 by thermal oxidation or selective oxide deposition, so as to reach the level of the upper face of the layer 34.

According to one embodiment, the region 44 is formed by depositing a layer of the material of the region 44, for example made of oxide, over the entire structure. According to this embodiment, the deposition of said layer is such that the upper face of said layer is flat and higher than the level of the upper face of the layer 34. The method further comprises removing portions of said layer located outside the cavity 36 by dry etching, during which the layer 34 serves as an etch stop layer.

FIG. 4C illustrates a structure resulting from a step in a manufacturing method of the device shown in FIG. 3.

During this step, the layer 34 is removed, preferably completely removed. The layer 34 is, for example, etched. The side walls of the layer 220, that is, the transistor emitter 42, and the region 44, are at least partially exposed. The upper face of the layer 32 is, for example, fully exposed.

FIG. 4D illustrates a structure resulting from an optional step in a manufacturing method of the device shown in FIG. 3.

During this step, the peripheral portions of the layer 220 are etched away. More specifically, a peripheral portion of the layer 220, surrounding a central portion of the layer 220, is removed. Thus, a portion of the lower face of the region 44 and a portion of the upper face of the layer 20 are exposed.

Removal of said peripheral portion is carried out, for example, by selective etching according to the doping level, so as to etch the layer 220 but not the layer 20. Removal of said peripheral portion is carried out, for example, by dry anisotropic plasma etching. For example, said portion is removed to a depth substantially equal to 20 nm.

The formation of the layer 20 results in the formation of defects, or "facets", on the peripheral portion of the layer 20. Removal of the peripheral portions of the layer 220 is carried out in such a way that the layer 220 does not cover portions of the layer 20 comprising these defects.

FIG. 4E illustrates a structure resulting from a step in a manufacturing method of the device shown in FIG. 3.

During this step, a layer 46 of dielectric material is formed, preferably in a conformal manner, on the structure resulting from the step in FIG. 4D. Thus, the layer 46 covers, and is preferably in contact with, the region 44, the layer 220, in particular the side faces of the layer 220, the upper face of the layer 32. The layer 46 is made, for example, of the same material as the region 44 and the layer 32, for example made of silicon oxide.

FIG. 4F illustrates a structure resulting from a step in a manufacturing method of the device shown in FIG. 3.

The step shown in FIG. 4F comprises an anisotropic etching step of the layer 46 and of the layer 32. The etching is preferably maintained until the layer 46 and the layer 32 are etched at the top of the region 44 and onto the layer 30. Since the region 44 is thicker than the layer 32, the region 44 is not fully etched by the anisotropic etching. The upper face of the layer 220 is therefore still completely covered by the region 44.

The etching of the layers 32 and 46 thus enables portions of the layers 32 and 46 encapsulating the layer 220 to be retained. In this way, all sides of the layer 220 are covered by the layer 32, the layer 46, the layer 20 or the region 44. The upper face of the layer 30 is thus exposed, preferably entirely except for the portions located directly around the layer 220.

The manufacturing method further comprises steps following the step described in relation to FIG. 4F. For example, the method comprises the step described in relation to FIG. 2H applied to the structure of FIG. 4F.

The manufacturing method also comprises, for example, a step of removing the layer 30, a step of growing the layer 24, a step for removing the layers 32 and 46 and the region 44 forming the encapsulation, and the formation of the spacers 26 on the walls of the layer 220.

FIG. 5 illustrates a further embodiment of an electronic device 50. The device 50 comprises a bipolar transistor 52.

The device 50 comprises the elements of the device 10 shown in FIG. 1. With the exception of the layer 22, the elements of the device 10 are present in the device 50 as described in relation to FIG. 1. Thus, the device 50 comprises the support 14, the collector 15, the dielectric layer 16, the intrinsic base 18, the extrinsic base 28, the semiconductor layer 20 and the spacers 26.

The device 50 comprises a layer 221. The layer 22 of the device 50 differs from the layer 22 of the device 10 in that the horizontal dimensions of the layer 22 of the device 50 are greater than the horizontal dimensions of the layer 22 of the device 10. In particular, the horizontal dimensions of the layer 22 of the device 50 are greater than the horizontal dimensions of the layers 18 and 20. Part of the upper face of the layer 24 is thus covered by the layer 22. Like the layers 20 and 22 in FIG. 1, the layer 20 and the layer 221 are not separated, even partially, by an insulating layer.

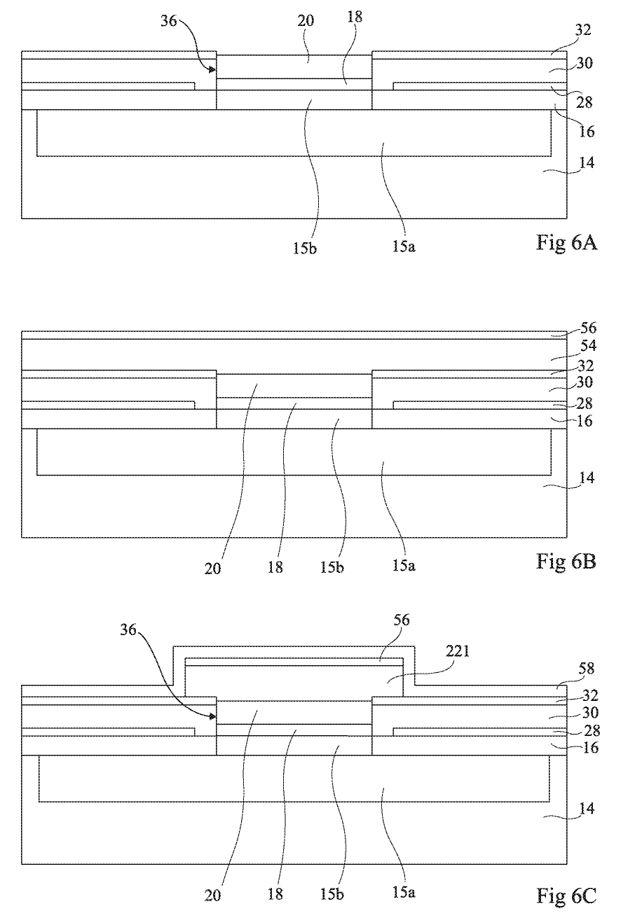

FIG. 6A,6B, and 6C illustrate structures resulting from steps, preferably successive steps, in another embodiment of an electronic device manufacturing method.

FIG. 6A illustrates a structure resulting from a step in a manufacturing method of the device of FIG. 5. In particular, FIG. 6A represents a structure resulting from steps identical to those described in relation to FIGS. 2A to 2D, with the exception of the layer 34, which is not formed during the step resulting in the structure of FIG. 6A. In the manufacturing method of the device of FIG. 5, the cavity 36 is made in the stack comprising, preferably only, the layers 18, 28, 30, 32 and not comprising the layer 34.

FIG. 6B illustrates a structure resulting from a step in a manufacturing method of the device shown in FIG. 5.

During this step, a layer 54 made of the material of the layer 221 is formed on the structure shown in FIG. 6A. The layer 54 is preferably formed by non-selective epitaxy. The layer 54 is thus formed by epitaxial growth on the layer 32 and on the layer 20. The layer 54 preferably has the same height as the desired layer 221.

The step shown in FIG. 6B also includes the formation of a layer 56. The layer 56 covers, preferably completely, the upper side of the layer 54. The layer 56 is made of a dielectric material, for example the same material as the layer 32, for example made of silicon oxide. The layer 56 is preferably thicker than the layer 32.

As in the method shown in FIGS. 2A to 2H, the layer 20 and the layer 221 are not separated, even partially, by an insulating layer. The method does not include, between the formation of the layer 20 and the formation of the layer 221, the formation of a dielectric layer in the cavity 36. The method does not include, between the formation of the layer 20 and the formation of the layer 221, the formation of spacers in the cavity 36.

FIG. 6C illustrates a structure resulting from a step in a manufacturing method of the device shown in FIG. 5.

The step shown in FIG. 6C involves etching the layers 54 and 56 to form the layer 221, such that the upper face of the layer 221 is completely covered by the layer 56. The horizontal dimensions of the region 221 are greater than the horizontal dimensions of the cavity 36. In this way, a portion of the layer 32 surrounding the cavity 36 is covered by the layer 221.

During this step, a layer 58 made of a dielectric material is formed, preferably in a conformal manner, on the structure resulting from the etching of the layers 54 and 56. In this way, the layer 58 covers, and is preferably in contact with, the layers 221, 32 and 56, in particular the side faces of the layer 221, the upper face of the layer 32, and the upper face and side faces of the layer 56. The layer 58 is, for example, made of the same material as layers 32 and 56, for example made of silicon oxide.

The manufacturing method further comprises steps following the step described in connection with FIG. 6C. For example, the method comprises the step described in relation to FIG. 4F applied to the structure of FIG. 6C, that is, comprises a step of anisotropic etching of the layer 58 and the layer 32. The etching step of the layers 32 and 58 thus makes it possible to retain portions of the layers 32 and 58 encapsulating the layer 221. Since the layer 56 is thicker than the layer 32, the layer 56 is not fully etched by the anisotropic etching method. The upper face of the layer 221 is therefore still entirely covered by the layer 56.

The manufacturing method of the device shown in FIG. 5 also comprises, for example, a step for removing the layer 30, a step for growing the layer 24, a step for removing the layers 32, 56, 58 forming the encapsulation and the formation of the spacers 26 on the walls of the layer 221.

An advantage of the embodiments described is that the emitter region does not include any deformation at the upper face of the emitter that might be caused by an insulating layer partially separating the layer 20 and the emitter.

Another advantage of the described embodiments is that it is possible to reduce transistor dimensions. Indeed, the cavity in which the intrinsic base is formed can have the horizontal dimensions of the desired interface between the intrinsic base and the emitter. There is no need for a larger cavity, as in the case where a dielectric layer separates part of the intrinsic base from part of the extrinsic base.

An advantage of the embodiments described in relation to FIGS. 3 and 4A to 4F is that it is not necessary to form an etch mask of the layer 46 during encapsulation. Such a mask could be poorly positioned, leading to the risk of misplacement of the encapsulation.

An advantage of the described embodiments, and in particular of the embodiment described in relation to FIGS. 5 and 6A to 6C, is that the thickness of the emitter can be less than that of a structure comprising spacers in the cavity.

Various embodiments and variants have been described. The person skilled in the art will understand that certain features of these various embodiments and variants could be combined, and other variants will become apparent to the person skilled in the art.

Finally, the practical implementation of the modes of realization and variants described is within the reach of the person skilled in the art on the basis of the functional indications given above.

1. A method of manufacturing an electronic device comprising a bipolar transistor, the method comprising steps:
a) forming an intrinsic base region; then
b) forming an emitter region;
wherein the method does not comprise formation of a layer of dielectric material separating the intrinsic base region and the emitter region.

2. The method according to claim 1, further comprising, prior to step a), steps:
c) forming a first part of a collector region of the transistor in a support;
d) forming a stack of dielectric layers on the support, the stack comprising, from the support, a second layer of dielectric material, a third layer of dielectric material, and a fourth layer of dielectric material; and
e) forming a cavity through the stack so as to reach the first part of the collector region;
where the intrinsic base region is formed, in step a), in the cavity.

3. The method according to claim 2, wherein the method does not comprise formation of a spacer in the cavity.

4. The method according to claim 2, wherein at least one horizontal dimension of the cavity is less than 150 nm.

5. The method according to claim 2, further comprising, between steps a) and b), step f) forming a layer of semiconductor material in the cavity, wherein the method does not comprise formation of a layer of dielectric material separating the layer of semiconductor material from the emitter region.

6. The method according to claim 5, wherein each of steps b) and f) includes an epitaxy of semiconductor material in the cavity, and wherein at least one horizontal dimension of the cavity is less than 150 nm.

7. The method according to claim 2, wherein step b) further includes filling the cavity to form the emitter region.

8. The method according to claim 2, further comprising, after step b), step g) forming a fifth layer of dielectric material so as to fill the cavity.

9. The method according to claim 8, wherein step d) comprises forming a sixth layer of dielectric material of the stack, and wherein the method further comprises, after step b), step h) removing the sixth layer of dielectric material.

10. The method according to claim 2, wherein step b) comprises steps:
b1) forming a layer of the material of the emitter region, the layer of the material of the emitter region covering the fourth layer of dielectric material;
b2) forming a seventh layer of dielectric material covering the layer of the material of the emitter region; and
b3) partially etching the layer of the material of the emitter region and the seventh layer of dielectric material.

11. The method according to claim 2, further comprising, after step b), steps:
i) forming an eighth layer of a dielectric material, in a conformal manner, on the device;
j) etching the fourth and eighth layers of dielectric materials so as to encapsulate the emitter region;
k) removing the third layer of dielectric material; and
l) forming an extrinsic base region of the transistor.

12. The method according to claim 11, wherein step j) comprises forming an etch mask covering the emitter region.

13. The method according to claim 11, wherein step j) comprises anisotropic etching.

14. The method according to claim 11, further comprising, between steps h) and i), etching a peripheral portion of the emitter region.

15. The method according to claim 11, wherein step l) includes an epitaxy of semiconductor material forming the extrinsic base region.

16. The method according to claim 11, further comprising, between steps e) and a) forming a second part of the collector region in the cavity and on the first part of the collector region.

17. An electronic device comprising a bipolar transistor, the bipolar transistor comprising an intrinsic base region and an emitter region and not comprising a layer of dielectric material separating the intrinsic base region and the emitter region.

18. The device of claim 17, wherein the emitter region has side walls that are coplanar with the side walls of the intrinsic base region.

19. The device according to claim 17, in which the emitter region extends partially opposite to the intrinsic base region.

20. The device according to claim 17, wherein the emitter region extends opposite the entirety of the intrinsic base region and partially opposite to the extrinsic base region.
